(19) United States
(12) Patent Application Publication
(10) Pub. No.: US 2025/0293077 A1
(43) Pub. Date: Sep. 18, 2025

(54) FILM ADHESIVE, DICING AND DIE-BONDING INTEGRAL FILM, SEMICONDUCTOR DEVICE, AND MANUFACTURING METHOD FOR SAME

(71) Applicant: Resonac Corporation, Minato-ku, Tokyo (JP)

(72) Inventors: Takahiro KURODA, Minato-ku, Tokyo (JP); Takaaki NIWA, Minato-ku, Tokyo (JP)

(21) Appl. No.: 18/860,697

(22) PCT Filed: Mar. 14, 2024
(86) PCT No.: PCT/JP2024/010073

§ 371 Date: Oct. 28, 2024

(30) Foreign Application Priority Data
Mar. 15, 2023 (WO) PCT/JP2023/010166
Aug. 9, 2023 (WO) PCT/JP2023/029152

(51) Int. Cl. H01L 21/683; C09J 7/35; C09J 163/00; H01L 21/78; H01L 23/00; H01L 25/065; H10B 80/00

(52) U.S. Cl. CPC H01L 21/6836; C09J 7/35; C09J 163/00; H01L 21/78; H01L 24/29; H01L 24/32; H01L 24/83; H01L 25/0657; H10B 80/00; C09J 2203/326; C09J 2301/208; C09J 2301/21; C09J 2301/304; C09J 2463/00; H01L 24/48; H01L 24/73; H01L 24/85; H01L 24/92; H01L 2221/68327; H01L 2221/68377; H01L 2224/29191; H01L 2224/32145; H01L 2224/32225; H01L 2224/32245; H01L 2224/48225; H01L 2224/48245; H01L 2224/73265; H01L 2224/83862; H01L 2224/85203; H01L 2224/85205; H01L 2224/92247; H01L 2225/0651; H01L 2924/1438; H01L 2924/3511; H01L 2924/3512

(57) ABSTRACT

A film-shaped adhesive contains a thermosetting resin component and an elastomer. In a DSC curve of the film-shaped adhesive obtained by performing differential scanning calorimetry under conditions of a temperature raising rate of 10° C./min and a measurement temperature range of 30 to 300° C., an onset temperature of an exothermic peak observed in the DSC curve is 165° C. or lower, a peak temperature is 185° C. or lower, and a calorific value is 90 J/g or more.

### TECHNICAL FIELD

The present disclosure relates to a film-shaped adhesive, a dicing/die-bonding integrated film, and a semiconductor device and a method for producing the same.

### BACKGROUND ART

In recent years, a Stacked Multi Chip Package (MCP) in which semiconductor chips are stacked in multiple stages has become widespread, and is mounted as a memory semiconductor package or the like for a mobile phone or a mobile audio device. In addition, with multi-functionalization of mobile phones and the like, high-speed, high-density, high-integration, and the like of semiconductor packages are also promoted.

As a method for producing a semiconductor device, a method in which a dicing/die-bonding integrated film including an adhesive layer and a pressure-sensitive adhesive layer is stuck to a back surface of a semiconductor wafer, and then the semiconductor wafer, the adhesive layer, and the pressure-sensitive adhesive layer are partially cut and singulated (semiconductor wafer back surface sticking method) is generally used. For example, Patent Literatures 1 and 2 disclose a film-shaped adhesive used for an adhesive layer in such a method.

### CITATION LIST

### Patent Literature

Patent Literature 1: WO 2013/133275 A1
Patent Literature 2: WO 2020/013250 A1

### SUMMARY OF INVENTION

### Technical Problem

In recent semiconductor packages, in a semiconductor chip including a circuit layer and a semiconductor layer, the circuit layer tends to be thick and the semiconductor layer tends to be thin. In such a semiconductor package, for example, a chip crack may occur when semiconductor chips are connected using wire bonding. It is presumed that such a chip crack occurs by vibration during wire bonding because the semiconductor layer becomes thin and the semiconductor chip becomes brittle. Therefore, a film-shaped adhesive used for a dicing/die-bonding integrated film is required to be able to prevent the occurrence of chip cracks.

In addition, in recent years, in a film-shaped adhesive, lowering of a curing temperature and shortening of a curing time have been studied, and a film-shaped adhesive used for a dicing/die-bonding integrated film is also required to be sufficiently cured under heating conditions of a low temperature and a short time (for example, conditions of 140° C. and 30 minutes).

Therefore, a main object of the present disclosure is to provide a film-shaped adhesive capable of sufficiently preventing the occurrence of chip cracks even when the film-shaped adhesive is cured under heating conditions of a low temperature and a short time.

### Solution to Problem

The present inventors have extensively conducted studies for achieving the above-mentioned object, and resultantly found that in a DSC curve of a film-shaped adhesive obtained by performing differential scanning calorimetry under predetermined conditions, when an onset temperature, a peak temperature, and a calorific value of an exothermic peak observed in the DSC curve are in predetermined ranges, the storage modulus of a cured product of the film-shaped adhesive can be improved even in a case where the film-shaped adhesive is cured under heating conditions of a low temperature and a short time, and the occurrence of chip cracks can be prevented, leading to completion of the invention of the present disclosure.

The present disclosure provides a film-shaped adhesive according to [1] to [8], a dicing/die-bonding integrated film according to [9], a semiconductor device according to [10] and [11], and a method for producing a semiconductor device according to [12] to [17].

[1] A film-shaped adhesive, containing: a thermosetting resin component; and an elastomer, in which
in a DSC curve of the film-shaped adhesive obtained by performing differential scanning calorimetry under conditions of a temperature raising rate of 10° C./min and a measurement temperature range of 30 to 300° C., an onset temperature of an exothermic peak observed in the DSC curve is 165° C. or lower, a peak temperature is 185° C. or lower, and a calorific value is 90 J/g or more.

[2] The film-shaped adhesive according to [1], optionally further containing an inorganic filler, in which
a content of the inorganic filler is 0 to 25% by mass with respect to a total amount of the film-shaped adhesive.

[3] The film-shaped adhesive according to [1] or [2], in which the thermosetting resin component contains an epoxy resin.

[4] The film-shaped adhesive according to [3], in which the thermosetting resin component further contains a phenol resin.

[5] The film-shaped adhesive according to any one of [1] to [4], in which a thickness of the film-shaped adhesive is 1 to 15 μm.

[6] The film-shaped adhesive according to any one of [1] to [5], in which a cured product obtained when a storage modulus at 150° C. of the film-shaped adhesive is cured under conditions of 140° C. and 30 minutes is 80 MPa or more.

[7] The film-shaped adhesive according to any one of [1] to [6], in which the film-shaped adhesive is used in a process for producing a semiconductor device formed by stacking a plurality of semiconductor chips.

[8] The film-shaped adhesive according to [7], in which the semiconductor device is a three-dimensional NAND memory.

[9] A dicing/die-bonding integrated film, including: a base material layer; a pressure-sensitive adhesive layer; and an adhesive layer made of the film-shaped adhesive according to any one of [1] to [6], in this order.

[10] A semiconductor device, including:
a first semiconductor chip;
a support member mounted with the first semiconductor chip; and
a cured product of the film-shaped adhesive according to any one of [1] to [6], the cured product being provided between the first semiconductor chip and the support member and bonding the first semiconductor chip to the support member.

[11] The semiconductor device according to [10], further including a second semiconductor chip different from the first semiconductor chip, the second semiconductor chip being stacked on a surface of the first semiconductor chip.

[12] A method for producing a semiconductor device, the method including:
sticking the adhesive layer of the dicing/die-bonding integrated film according to [9] to a semiconductor wafer;
preparing a plurality of singulated semiconductor chips with an adhesive piece by cutting the semiconductor wafer with the adhesive layer stuck thereto; and
bonding, as the semiconductor chip with an adhesive piece, a first semiconductor chip with an adhesive piece having a first semiconductor chip and a first adhesive piece to a support member via the first adhesive piece.

[13] The method for producing a semiconductor device according to [12], further including:
thermally curing the first adhesive piece in the first semiconductor chip with an adhesive piece under conditions of 100 to 180° C. and 15 to 60 minutes; and
electrically connecting the first semiconductor chip to the support member with a bonding wire.

[14] The method for producing a semiconductor device according to [12], further including: bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece.

[15] The method for producing a semiconductor device according to [14], further including:
thermally curing the first adhesive piece in the first semiconductor chip with an adhesive piece and the second adhesive piece in the second semiconductor chip with an adhesive piece under conditions of 100 to 180° C. and 15 to 60 minutes; and
electrically connecting the first semiconductor chip and the second semiconductor chip to the support member with a bonding wire.

[16] A method for producing a semiconductor device, the method including: interposing the film-shaped adhesive according to any one of [1] to [6] between a first semiconductor chip and a support member, or between a first semiconductor chip and a second semiconductor chip different from the first semiconductor chip, and bonding the first semiconductor chip and the support member, or the first semiconductor chip and the second semiconductor chip.

[17] The method for producing a semiconductor device according to [16], further including:
thermally curing the film-shaped adhesive under conditions of 100 to 180° C. and 15 to 60 minutes; and
electrically connecting the first semiconductor chip and the second semiconductor chip to the support member with a bonding wire.

### Advantageous Effects of Invention

According to the present disclosure, a film-shaped adhesive capable of sufficiently preventing the occurrence of chip cracks even when the film-shaped adhesive is cured under heating conditions of a low temperature and a short time is provided. Further, according to the present disclosure, a dicing/die-bonding integrated film, and a semiconductor device and a method for producing the same, in each of which such a film-shaped adhesive is used, are provided. Further, according to the present disclosure, a method for producing a semiconductor device using such a dicing/die-bonding integrated film is provided.

### BRIEF DESCRIPTION OF DRAWINGS

FIG. 1 is a schematic cross-sectional view showing one embodiment of a film-shaped adhesive.

FIG. 2 is a schematic view showing a method for obtaining an onset temperature and a peak temperature of an exothermic peak from a DSC curve.

FIG. 3 is a schematic view showing a method for obtaining a calorific value of an exothermic peak from a DSC curve.

FIG. 4 is a schematic cross-sectional view showing one embodiment of a dicing/die-bonding integrated film.

FIG. 5 is a schematic cross-sectional view showing one embodiment of a semiconductor device.

FIG. 6 is a schematic cross-sectional view showing another embodiment of a semiconductor device.

FIG. 7 is a schematic cross-sectional view showing another embodiment of a semiconductor device.

### DESCRIPTION OF EMBODIMENTS

Hereinafter, embodiments of the present disclosure will be described with appropriate reference to the drawings. However, the present disclosure is not limited to the following embodiments. In the following embodiments, the constituent elements (including steps and the like) are not essential unless otherwise specified. The sizes of the constituent elements in the drawings are conceptual, and the relative relationship between the sizes of the constituent elements is not limited to that shown in the drawings.

The same applies to numerical values and ranges thereof in the present disclosure, and the present disclosure is not limited thereto. In the present description, a numerical range indicated using “to” indicates a range including numerical values described before and after “to” as a minimum value and a maximum value, respectively. In the numerical ranges described in stages in the present description, the upper limit value or the lower limit value described in one numerical range may be replaced with the upper limit value or the lower limit value of a numerical range described in another stage. In addition, in a numerical range described in the present description, the upper limit value or the lower limit value of the numerical range may be replaced with a value shown in Examples. In addition, the upper limit value and the lower limit value described individually can be arbitrarily combined. In addition, “A or B” only needs to include either A or B, and may include both A and B. In addition, as for the materials exemplified below, one type may be used alone or two or more types may be used in combination unless otherwise specified. When a plurality of substances corresponding to each component are present in a composition, the content of each component in the composition means the total amount of the plurality of substances present in the composition unless otherwise specified.

In the present description, a (meth)acrylate means an acrylate or a methacrylate corresponding thereto. The same applies to other similar expressions such as a (meth)acryloyl group and a (meth)acrylic copolymer.

### [Film-Shaped Adhesive]

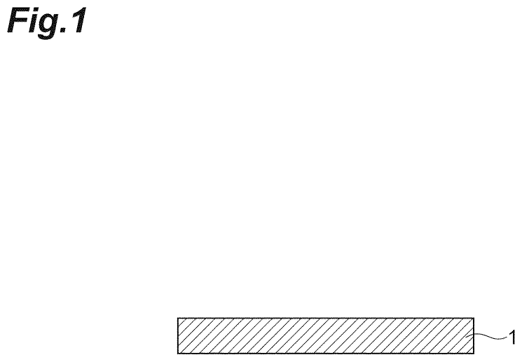

FIG. 1 is a schematic cross-sectional view showing one embodiment of a film-shaped adhesive. A film-shaped adhesive 1 (adhesive film) shown in FIG. 1 may be thermosetting, and may be one that can be in a completely cured (C-stage) state after a curing treatment through a semi-cured (B-stage) state.

The film-shaped adhesive 1 contains a thermosetting resin component (hereinafter sometimes referred to as “component (A)”) and an elastomer (hereinafter sometimes referred to as “component (B)”), and may further contain an inorganic filler (hereinafter sometimes referred to as “component (C)”). The component (A) may contain, for example, an epoxy resin (hereinafter sometimes referred to as “component (A1)”) and a phenol resin (hereinafter sometimes referred to as “component (A2)”). The film-shaped adhesive 1 may further contain a coupling agent (hereinafter sometimes referred to as “component (D)”), a curing accelerator (hereinafter sometimes referred to as “component (E)”), other components, and the like in addition to the component (A), the component (B), and the component (C).

The film-shaped adhesive 1 is a film-shaped adhesive, in which in a DSC curve obtained by performing differential scanning calorimetry under conditions of a temperature raising rate of 10° C./min and a measurement temperature range of 30 to 300° C., an onset temperature of an exothermic peak observed in the DSC curve is 165° C. or lower, a peak temperature is 185° C. or lower, and a calorific value is 90 J/g or more. In the DSC curve, there may be a plurality of exothermic peaks. In this case, the target exothermic peak can be an exothermic peak indicating the largest calorific value.

In the present description, the differential scanning calorimetry is performed by heating a sample in an air or nitrogen atmosphere by setting the sample amount of the film-shaped adhesive 1 to serve as a sample to 10±0.5 mg, the temperature raising rate to 10° C./min, and the measurement temperature range to 30 to 300° C.

A conventional film-shaped adhesive usually has an exothermic peak in a temperature range of 30 to 300° C. in a DSC curve. It is presumed that the heat generation in this temperature range is heat generation derived from a curing reaction of the thermosetting resin component (for example, a reaction between an epoxy resin and a phenol resin). Since the onset temperature of the exothermic peak is 165° C. or lower, the peak temperature is 185° C. or lower, and the calorific value is 90 J/g or more, the film-shaped adhesive of the present embodiment can improve the storage modulus of a cured product of the film-shaped adhesive even when curing is performed under heating conditions of a low temperature and a short time, and can prevent the occurrence of chip cracks.

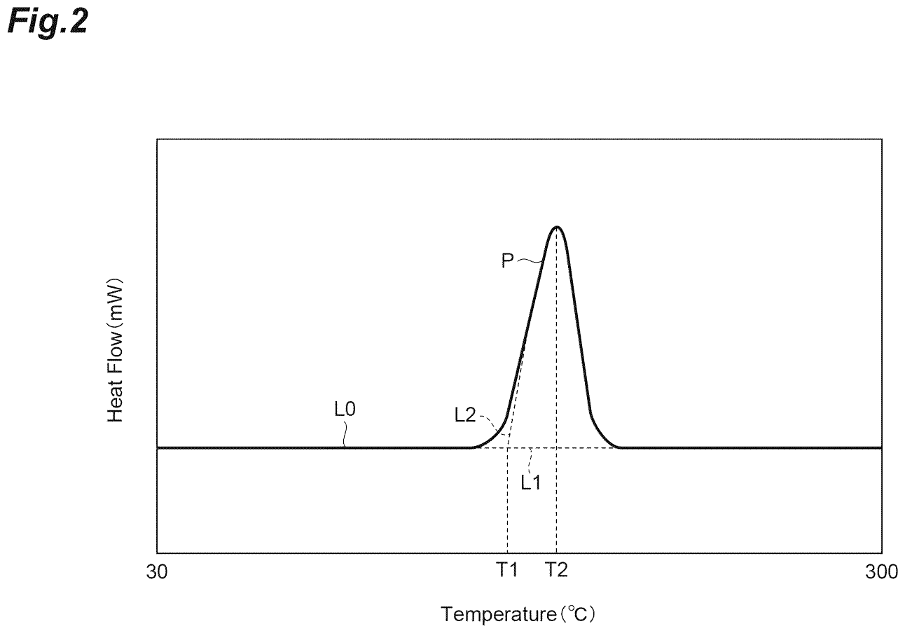

FIG. 2 is a schematic view showing a method for obtaining an onset temperature and a peak temperature of an exothermic peak from a DSC curve. The DSC curve shown in FIG. 2 includes a baseline L0 and an exothermic peak P due to a curing reaction of the film-shaped adhesive 1 observed in the middle of the baseline L0 in a temperature region of 30 to 300° C. A temperature T1 at the intersection point of an extended line L1 of the baseline L0 at the lower portion of the exothermic peak P and a tangent L2 of the DSC curve at a point where the DSC curve shows the maximum gradient at the exothermic peak P is the onset temperature. A temperature T2 at the maximum point of the exothermic peak P is the peak temperature.

The onset temperature of the exothermic peak is 165° C. or lower, and may be, for example, 160° C. or lower or 155° C. or lower. When the onset temperature of the exothermic peak is 165° C. or lower, the film-shaped adhesive can be cured under heating conditions of a low temperature and a short time. The onset temperature of the exothermic peak may be, for example, 100° C. or higher, 110° C. or higher, or 120° C. or higher.

The peak temperature of the exothermic peak is 185° C. or lower, and may be, for example, 180° C. or lower or 175° C. or lower. When the peak temperature of the exothermic peak is 185° C. or lower, the curing reaction of the film-shaped adhesive sufficiently proceeds under heating conditions of a low temperature and a short time, and a desired storage modulus tends to be easily obtained. The peak temperature of the exothermic peak may be, for example, 140° C. or higher, 150° C. or higher, or 160° C. or higher.

The difference between the peak temperature and the onset temperature of the exothermic peak may be, for example, 45° C. or less, 40° C. or less, 35° C. or less, 30° C. or less, 25° C. or less, or 20° C. or less. When the difference between the peak temperature and the onset temperature of the exothermic peak is in such a range, the curing reaction of the film-shaped adhesive sufficiently proceeds under heating conditions of a low temperature and a short time, and a desired storage modulus tends to be easily obtained. The difference between the peak temperature and the onset temperature of the exothermic peak may be, for example, 5° C. or more or 10° C. or more.

The onset temperature and the peak temperature of the exothermic peak can be lowered, for example, by increasing the content of the component (E) in the film-shaped adhesive, changing the component (E) to one that acts at a lower temperature, increasing the content of the component (A) in the film-shaped adhesive, or the like.

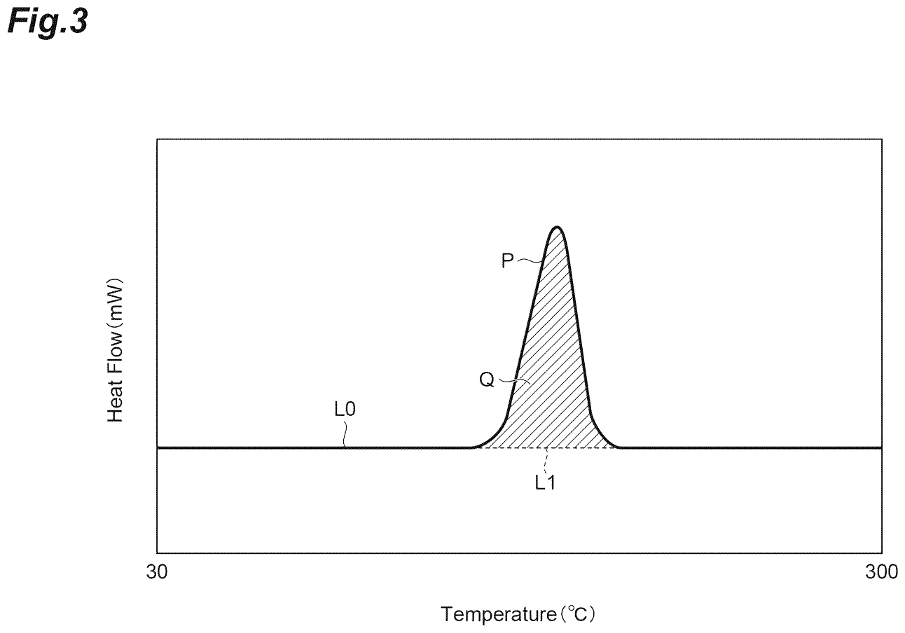

FIG. 3 is a schematic view showing a method for obtaining a calorific value of an exothermic peak from a DSC curve. The DSC curve shown in FIG. 3 is similar to the DSC curve shown in FIG. 2. As shown in FIG. 3, a calorific value Q is calculated by integrating the peak area of the exothermic peak P (the area of a region surrounded by the exothermic peak P and the extended line L1 of the baseline L0).

The calorific value of the exothermic peak is 90 J/g or more, and may be, for example, 95 J/g or more, 100 J/g or more, 105 J/g or more, 110 J/g or more, 115 J/g or more, 120 J/g or more, 125 J/g or more, or 130 J/g or more. When the calorific value of the exothermic peak is 90 J/g or more, the reaction rate of the curing reaction of the film-shaped adhesive can be sufficiently increased under heating conditions of a low temperature and a short time. The calorific value of the exothermic peak may be, for example, 250 J/g or less or 200 J/g or less.

The calorific value of the exothermic peak can be improved, for example, by increasing the content of the component (A) in the film-shaped adhesive, using a component having a smaller epoxy equivalent as the component (A1) of the component (A), increasing the ratio of the epoxy equivalent of the component (A1) to the hydroxyl equivalent of the component (A2) (epoxy equivalent of component (A1)/hydroxyl equivalent of component (A2)), or the like.

Hereinafter, the respective components constituting the film-shaped adhesive of the present embodiment will be described. By adopting the components shown below, there is a tendency that it is easy to prepare a film-shaped adhesive satisfying the conditions of the onset temperature, the peak temperature, and the calorific value of the exothermic peak.

### Component (A): Thermosetting Resin Component

### Component (A1): Epoxy Resin

The component (A1) can be used without particular limitation as long as it has an epoxy group in the molecule. Examples of the component (A1) include a bisphenol A type epoxy resin; a bisphenol F type epoxy resin; a bisphenol S type epoxy resin; a phenol novolac type epoxy resin; a cresol novolac type epoxy resin; a bisphenol A novolac type epoxy resin; a bisphenol F novolac type epoxy resin; a stilbene type epoxy resin; a triazine skeleton-containing epoxy resin; a fluorene skeleton-containing epoxy resin; a triphenolmethane type epoxy resin; a biphenyl type epoxy resin; a xylylene type epoxy resin; a biphenylaralkyl type epoxy resin; a naphthalene type epoxy resin; and a diglycidyl ether compound of a polycyclic aromatic such as a polyfunctional phenol or anthracene. Among these, the component (A1) may contain a cresol novolac type epoxy resin, a bisphenol F type epoxy resin, or a bisphenol A type epoxy resin from the viewpoint of tackiness, flexibility, and the like of the film. Many bisphenol F type epoxy resins have a relatively low softening point and a softening point of 40° C. or lower.

The component (A1) may contain an epoxy resin having a softening point of 40° C. or lower (or an epoxy resin that is liquid at 30° C., hereinafter sometimes referred to as “component (Ala)”). The component (A1) may be a combination of the component (Ala) and an epoxy resin having a softening point higher than 40° C. (or an epoxy resin that is solid at 30° C., hereinafter sometimes referred to as “component (A1b)”). When the component (A1) contains the component (Ala), the storage modulus after curing tends to be more easily improved. In addition, when the component (A1) is a combination of the component (A1a) and the component (Alb), film thinning tends to be more easily achieved.

In the present description, the softening point means a value measured by a ring and ball method in accordance with JIS K 7234:1986.

Examples of a commercially available product of the component (A1a) include EXA-830CRP (trade name, manufactured by DIC Corporation, liquid at 30° C.), YDF-8170C (trade name, manufactured by NIPPON STEEL Chemical & Material Co., Ltd., liquid at 30° C.), and EP-4088S (trade name, manufactured by ADEKA CORPORATION, liquid at 30° C.).

When the component (A1) is a combination of the component (A1a) and the component (A1b), the content of the component (A1a) may be 5% by mass or more, 10% by mass or more, or 15% by mass or more, and may be 80% by mass or less, 70% by mass or less, or 65% by mass or less with respect to the total amount of the component (A1). The content of the component (A1a) in the component (A1) in an adhesive composition when the film-shaped adhesive is formed may be similar to the above range.

When the component (A1) is a combination of the component (A1a) and the component (Alb), the content of the component (A1b) may be 20% by mass or more, 30% by mass or more, or 35% by mass or more, and may be 95% by mass or less, 90% by mass or less, or 85% by mass or less with respect to the total amount of the component (A1). The content of the component (Alb) in the component (A1) in the adhesive composition when the film-shaped adhesive is formed may be similar to the above range.

The epoxy equivalent of the component (A1) is not particularly limited, but may be 90 to 300 g/eq or 110 to 290 g/eq. When the epoxy equivalent of the component (A1) is in such a range, the fluidity of the adhesive composition tends to be easily ensured when the film-shaped adhesive is formed while the bulk strength of the film-shaped adhesive is maintained.

### Component (A2): Phenol Resin

The component (A2) can be a component that acts as a curing agent for the component (A1), that is, a curing agent for an epoxy resin. When the film-shaped adhesive contains the component (A2), the film-shaped adhesive is highly crosslinked, and the storage modulus after curing can be improved.

The component (A2) can be used without particular limitation as long as it has a phenolic hydroxyl group in the molecule. The component (A2) is not particularly limited as long as it has a phenolic hydroxyl group in the molecule. Examples of the component (A2) include a novolac type phenol resin obtained by condensation or co-condensation of a phenol such as phenol, cresol, resorcin, catechol, bisphenol A, bisphenol F, phenylphenol, or aminophenol and/or a naphthol such as α-naphthol, β-naphthol, or dihydroxynaphthalene with a compound having an aldehyde group such as formaldehyde in the presence of an acidic catalyst; a phenol aralkyl resin synthesized from a phenol such as allylated bisphenol A, allylated bisphenol F, allylated naphthalenediol, phenol novolac, or phenol and/or a naphthol with dimethoxyparaxylene or bis(methoxymethyl)biphenyl; a naphthol aralkyl resin; a biphenylaralkyl type phenol resin; and a phenyl aralkyl type phenol resin. Among these, the phenol resin may contain a novolac type phenol resin or a phenyl aralkyl type phenol resin.

The hydroxyl equivalent of the component (A2) may be 70 g/eq or more or 70 to 300 g/eq. When the hydroxyl equivalent of the component (A2) is 70 g/eq or more, the storage modulus tends to be further improved, and when the hydroxyl equivalent is 300 g/eq or less, it is possible to prevent defects due to foaming or generation of outgas or the like.

The softening point of the component (A2) is not particularly limited, but may be, for example, 90° C. or higher, 100° C. or higher, or 110° C. or higher. The upper limit of the softening point of the component (A2) may be, for example, 200° C. or lower.

Examples of a commercially available product of the component (A2) include PSM-4326 (trade name, manufactured by Gun Ei Chemical Industry Co., Ltd., softening point: 120° C.), J-DPP-140 (trade name, manufactured by JFE Chemical Corporation, softening point: 140° C.), and GPH-103 (trade name, manufactured by Nippon Kayaku Co., Ltd., softening point: 99 to 106° C.).

The ratio of the epoxy equivalent of the component (A1) to the hydroxyl equivalent of the component (A2) (epoxy equivalent of component (A1)/hydroxyl equivalent of component (A2)) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When the equivalent ratio is 0.30/0.70 or more, more sufficient curability tends to be obtained. When the equivalent ratio is 0.70/0.30 or less, the viscosity can be prevented from becoming too high, and more sufficient fluidity can be obtained.

The content of the component (A1) (the sum of the component (A1a) and the component (Alb)) may be 20% by mass or more, and may be 22% by mass or more, 25% by mass or more, 28% by mass or more, 30% by mass or more, 32% by mass or more, 35% by mass or more, 38% by mass or more, or 40% by mass or more with respect to the total amount of the film-shaped adhesive. When the content of the component (A1) is in such a range, the storage modulus after curing tends to be more easily improved. The content of the component (A1) may be 50% by mass or less, 48% by mass or less, or 45% by mass or less with respect to the total amount of the film-shaped adhesive from the viewpoint of handleability. The content of the component (A1) (the sum of the component (A1a) and the component (A1b)) in the adhesive composition when the film-shaped adhesive is formed may be similar to the above range.

The content of the component (A2) may be 10% by mass or more, and may be 12% by mass or more, 15% by mass or more, 18% by mass or more, 20% by mass or more, 22% by mass or more, or 25% by mass or more with respect to the total amount of the film-shaped adhesive. When the content of the component (A2) is in such a range, the storage modulus after curing tends to be more easily improved. The content of the component (A2) may be 35% by mass or less, 32% by mass or less, or 30% by mass or less with respect to the total amount of the film-shaped adhesive from the viewpoint of handleability. The content of the component (A2) in the adhesive composition when the film-shaped adhesive is formed may be similar to the above range.

The content of the component (A) (the sum of the component (A1) and the component (A2)) may be 35% by mass or more, and may be 38% by mass or more, 40% by mass or more, 42% by mass or more, 45% by mass or more, 48% by mass or more, 50% by mass or more, 52% by mass or more, 55% by mass or more, 58% by mass or more, 60% by mass or more, 62% by mass or more, or 65% by mass or more with respect to the total amount of the film-shaped adhesive. When the content of the component (A) is in such a range, the storage modulus after curing tends to be more easily improved. The content of the component (A) may be 80% by mass or less, 75% by mass or less, or 70% by mass or less with respect to the total amount of the film-shaped adhesive from the viewpoint of handleability. The content of the component (A) (the sum of the component (A1) and the component (A2)) in the adhesive composition when the film-shaped adhesive is formed may be similar to the above range.

### Component (B): Elastomer

Examples of the component (B) include an acrylic resin, a polyester resin, a polyamide resin, a polyimide resin, a silicone resin, a butadiene resin; and modified products of these resins. Examples of the component (B) include a polymer having an organopolysiloxane in a side chain. Among these, the component (B) may be an acrylic resin (acrylic rubber) containing a constituent unit derived from a (meth)acrylic acid ester as a main component because of containing less ionic impurities, being more excellent in heat resistance, being easier to ensure connection reliability of a semiconductor device, and having more excellent fluidity. The content of the constituent unit derived from the (meth)acrylic acid ester in the component (B) may be, for example, 70% by mass or more, 80% by mass or more, or 90% by mass or more with respect to the total amount of the constituent units. The acrylic resin (acrylic rubber) may contain a constituent unit derived from a (meth)acrylic acid ester having a crosslinkable functional group such as an epoxy group, an alcoholic or phenolic hydroxyl group, or a carboxyl group.

The glass transition temperature (Tg) of the component (B) may be 0 to 30° C. When the Tg of the component (B) is 0° C. or higher, the adhesive strength of the film-shaped adhesive can be further improved, and moreover, there is a tendency that the flexibility of the film-shaped adhesive can be prevented from becoming too high. When the Tg of the component (B) is 30° C. or lower, a decrease in flexibility of the film-shaped adhesive can be prevented, and the breaking strength when a thin film is formed is excellent, and also the processability tends to be excellent. The glass transition temperature (Tg) of the component (B) may be 5° C. or higher or 10° C. or higher, and may be 25° C. or lower or 20° C. or lower. Here, Tg means a value measured using a thermal differential scanning calorimeter (DSC) (for example, Thermo Plus 2 manufactured by Rigaku Corporation). The Tg of the component (B) can be adjusted within a desired range by adjusting the type and content of the constituent unit constituting the component (B) (when the component (B) is an acrylic resin (acrylic rubber), a constituent unit derived from a (meth)acrylic acid ester).

The weight average molecular weight (Mw) of the component (B) may be 100,000 or more, 300,000 or more, or 500,000 or more, and may be 3,000,000 million or less, 2,000,000 or less, or 1,000,000 or less. When the Mw of the component (B) is in such a range, the film formability, film strength, flexibility, tackiness, and the like can be appropriately controlled, and also the reflowability is excellent, and the embeddability can be improved. Here, Mw means a value obtained by measurement with gel permeation chromatography (GPC) and conversion using a standard polystyrene calibration curve. When a plurality of peaks are observed in GPC, a weight average molecular weight derived from a peak with the highest peak intensity is defined as the weight average molecular weight in the present description.

Examples of a commercially available product of the component (B) include SG-P3 and SG-80H (both manufactured by Nagase ChemteX Corporation) and KH-CT-865 (manufactured by Resonac Corporation).

The content of the component (B) may be 15% by mass or more, 20% by mass or more, or 25% by mass or more with respect to the total amount of the film-shaped adhesive. When the content of the component (B) is in such a range, the thin film formability is excellent, the breaking strength when a thin film is formed is excellent, and there is a tendency that warpage of a semiconductor device (semiconductor package) can be prevented. The content of the component (B) may be 45% by mass or less, 40% by mass or less, or 35% by mass or less with respect to the total amount of the film-shaped adhesive. When the content of the component (B) is in such a range, the storage modulus after curing tends to be more easily improved. The content of the component (B) in the adhesive composition when the film-shaped adhesive is formed may be similar to the above range.

### Component (C): Inorganic Filler

The film-shaped adhesive 1 may further contain the component (C). That is, there may be an aspect in which the film-shaped adhesive 1 contains the component (C) and an aspect in which the film-shaped adhesive 1 does not substantially contain the component (C).

Examples of the component (C) include aluminum hydroxide, magnesium hydroxide, calcium carbonate, magnesium carbonate, calcium silicate, magnesium silicate, calcium oxide, magnesium oxide, aluminum oxide, aluminum nitride, an aluminum borate whisker, boron nitride, and silica. Among these, the component (C) may be silica from the viewpoint of adjusting the melt viscosity. The shape of the component (C) is not particularly limited, but may be spherical.

The average particle diameter of the component (C) may be 0.7 μm or less, and may be 0.6 μm or less, 0.5 μm or less, 0.4 μm or less, or 0.3 μm or less from the viewpoint of fluidity and storage modulus. The average particle diameter of the component (C) may be, for example, 0.01 μm or more. Here, the average particle diameter means a particle diameter at a cumulative frequency of 50% in a particle size distribution obtained by a laser diffraction/scattering method. The average particle diameter of the component (C) can also be obtained using a film-shaped adhesive containing the component (C). In this case, a residue obtained by heating the film-shaped adhesive to decompose the resin component is dispersed in a solvent to prepare a dispersion, and the average particle diameter of the component (C) can be determined from a particle size distribution obtained by applying a laser diffraction/scattering method to the dispersion.

The content of the component (C) may be 0 to 25% by mass with respect to the total amount of the film-shaped adhesive. When the content of the component (C) is in such a range, there is a tendency for film thinning to be even more possible. In addition, when the content of the component (C) is in such a range, the breaking strength when a thin film is formed is excellent, the processability is also excellent, and there is a tendency that warpage of a semiconductor device (semiconductor package) can be prevented. In one embodiment, the content of the component (C) may be 22% by mass or less, 20% by mass or less, 17% by mass or less, 15% by mass or less, 12% by mass or less, 10% by mass or less, 7% by mass or less, 5% by mass or less, 4% by mass or less, 3% by mass or less, 2% by mass or less, 1% by mass or less, 0.5% by mass or less, or 0.1% by mass or less with respect to the total amount of the film-shaped adhesive. In one embodiment, the content of the component (C) may be 0% by mass with respect to the total amount of the film-shaped adhesive. That is, in one embodiment, the film-shaped adhesive need not contain the component (C). In one embodiment, the content of the component (C) may be 0% by mass or more, more than 0% by mass, 1% by mass or more, 3% by mass or more, or 5% by mass or more with respect to the total amount of the film-shaped adhesive. The content of the component (C) in the adhesive composition when the film-shaped adhesive is formed may be similar to the above range.

The component (A) and the component (B), or the component (A), the component (B), and the component (C) can be main components of the film-shaped adhesive of the present embodiment. The total content of the component (A) and the component (B) or the total content of the component (A), the component (B), and the component (C) may be, for example, 70% by mass or more, 80% by mass or more, 90% by mass or more, 95% by mass or more, 96% by mass or more, 97% by mass or more, 98% by mass or more, 99% by mass or more, 99.5% by mass or more, 99.7% by mass or more, or 99.9% by mass or more. The total content of the component (A) and the component (B) or the total content of the component (A), the component (B), and the component (C) may be, for example, 100% by mass or less, 99.9% by mass or less, 99.7% by mass or less, or 99.5% by mass or less.

### Component (D): Coupling Agent

The component (D) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane.

### Component (E): Curing Accelerator

Examples of the component (E) include an imidazole and a derivative thereof, an organophosphorus compound, a secondary amine, a tertiary amine, and a quaternary ammonium salt. Among these, the component (E) may be an imidazole and a derivative thereof from the viewpoint of reactivity.

Examples of the imidazole include 2-methylimidazole, 1-benzyl-2-methylimidazole, 2-phenylimidazole, 1-cyanoethyl-2-phenylimidazole, and 1-cyanoethyl-2-methylimidazole.

The component (E) may contain 2-phenylimidazole because it easily accelerates curing at a low temperature.

The film-shaped adhesive may further contain other components. Examples of the other components include a pigment, an ion scavenger, and an antioxidant.

The total content of the component (D), the component (E), and other components may be 0% by mass or more, 0.1% by mass or more, 0.3% by mass or more, or 0.5% by mass or more, and may be 30% by mass or less, 20% by mass or less, 10% by mass or less, 5% by mass or less, 4% by mass or less, 3% by mass or less, 2% by mass or less, or 1% by mass or less with respect to the total amount of the film-shaped adhesive. The total content of the component (D), the component (E), and other components in the adhesive composition when the film-shaped adhesive is formed may be similar to the above range.

The thickness of the film-shaped adhesive 1 may be 1 to 15 μm. The thickness of the film-shaped adhesive 1 may be 12 μm or less, 10 μm or less, 8 μm or less, or 7 μm or less. The thickness of the film-shaped adhesive 1 can be obtained, for example, by measuring the thickness of the cross-section of the film-shaped adhesive 1 at five positions in a scanning microscope photograph, and calculating the average of the measured values.

The storage modulus at 150° C. of a cured product obtained when the film-shaped adhesive 1 is cured under the conditions of 140° C. and 30 minutes may be 50 MPa or more, 55 MPa or more, 60 MPa or more, 65 MPa or more, 70 MPa or more, 75 MPa or more, 80 MPa or more, 85 MPa or more, 90 MPa or more, 95 MPa or more, 100 MPa or more, 105 MPa or more, 110 MPa or more, 115 MPa or more, 120 MPa or more, 125 MPa or more, 130 MPa or more, 135 MPa or more, 140 MPa or more, 145 MPa or more, or 150 MPa or more. When the storage modulus is 50 MPa or more, brittleness of a semiconductor chip due to film thinning can be compensated, and as a result, occurrence of chip cracks can be prevented. The upper limit of the storage modulus is not particularly limited, but may be, for example, 500 MPa or less, 300 MPa or less, 250 MPa or less, or 200 MPa or less.

In the present description, the storage modulus at 150° C. of a cured product obtained when the film-shaped adhesive is cured at 140° C. for 30 minutes can be measured, for example, by the following method. A plurality of film-shaped adhesives having a thickness of 5 μm are stacked to a thickness of 20 μm or more, and this is sized to a width of 4 mm×a length of 20 mm or more to prepare a sample for measurement. The prepared sample is cured under the conditions of 140° C. and 30 minutes, then the sample after curing is set in a dynamic viscoelasticity measuring device (Rheogel E-4000, manufactured by UBM Co., Ltd.), and dynamic viscoelasticity is measured in a temperature-dependent measurement mode in which measurement is performed from room temperature (25° C.) to 300° C. under the conditions of a chuck distance of 20 mm, a frequency of 10 Hz, and a temperature raising rate of 3° C./minute under a tensile load. Here, the value of the storage modulus at 150° C. is read, and the value is taken as the storage modulus at 150° C.

The film-shaped adhesive 1 (adhesive film) shown in FIG. 1 is obtained by molding an adhesive composition containing the component (A) and the component (B) and, if necessary, the component (C) and a component to be added into a film shape. Such a film-shaped adhesive 1 can be formed by applying the adhesive composition to a support film. In the formation of the film-shaped adhesive 1, a varnish (adhesive varnish) containing the adhesive composition and a solvent may be used. When the adhesive varnish is used, the component (A) and the component (B) and, if necessary, the component (C) and a component to be added are mixed or kneaded in a solvent to prepare an adhesive varnish, the obtained adhesive varnish is applied to a support film, and the solvent is removed by heating and drying, whereby the film-shaped adhesive 1 can be obtained.

The support film is not particularly limited as long as it withstands the heating and drying, and may be, for example, a polyester film, a polypropylene film, a polyethylene terephthalate film, a polyimide film, a polyetherimide film, a polyethylene naphthalate film, a polymethylpentene film, or the like. The support film may be a multilayer film obtained by combining two or more types, or may be surface-treated with a silicone-based or silica-based release agent or the like. The thickness of the support film may be, for example, 10 to 200 μm or 20 to 170 μm.

Mixing or kneading can be performed by using a normal disperser such as a stirrer, a crusher, a three-roll mill, or a ball mill, and appropriately combining these.

The solvent used for preparing the adhesive varnish is not limited as long as it can uniformly dissolve, knead, or disperse each component, and a conventionally known solvent can be used. Examples of such a solvent include ketone-based solvents such as acetone, methyl ethyl ketone, methyl isobutyl ketone, and cyclohexanone, dimethylformamide, dimethylacetamide, N-methylpyrrolidone, toluene, and xylene. The solvent may be methyl ethyl ketone or cyclohexanone from the viewpoint of drying speed and price.

As a method for applying the adhesive varnish to the support film, a known method can be used, and for example, a knife coating method, a roll coating method, a spray coating method, a gravure coating method, a bar coating method, a curtain coating method, or the like can be used. The heating and drying conditions are not particularly limited as long as the solvent used is sufficiently volatilized, but may be 50 to 150° C. and 1 to 30 minutes.

Since the film-shaped adhesive 1 enables film thinning, the film-shaped adhesive 1 can be suitably used in a process for producing a semiconductor device formed by stacking a plurality of semiconductor chips. In this case, the semiconductor device may be a stacked MCP or a three-dimensional NAND memory.

### [Dicing/Die-Bonding Integrated Film]

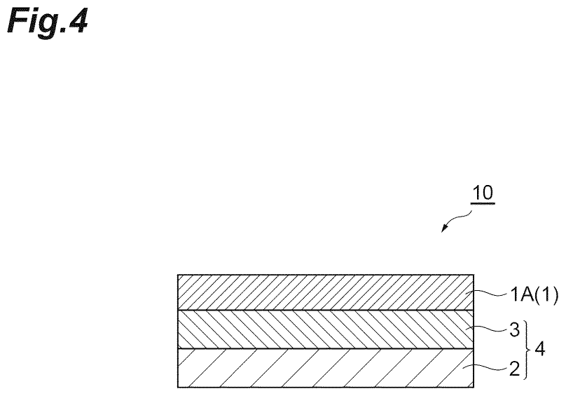

FIG. 4 is a schematic cross-sectional view showing one embodiment of a dicing/die-bonding integrated film. A dicing/die-bonding integrated film 10 shown in FIG. 4 includes a base material layer 2, a pressure-sensitive adhesive layer 3, and an adhesive layer 1A made of the film-shaped adhesive 1, in this order. The base material layer 2 and the pressure-sensitive adhesive layer 3 can be a dicing film 4. When such a dicing/die-bonding integrated film 10 is used, the lamination step on a semiconductor wafer is done only once, so that the work efficiency can be improved. The dicing/die-bonding integrated film may have a film shape, a sheet shape, a tape shape, or the like.

The dicing film 4 includes the base material layer 2 and the pressure-sensitive adhesive layer 3 provided on the base material layer 2.

Examples of the base material layer 2 include plastic films such as a polytetrafluoroethylene film, a polyethylene terephthalate film, a polyethylene film, a polypropylene film, a polymethylpentene film, and a polyimide film. These base material layers 2 may be subjected to a surface treatment such as primer application, a UV treatment, a corona discharge treatment, a polishing treatment, or an etching treatment as necessary.

The pressure-sensitive adhesive layer 3 is a layer made of a pressure-sensitive adhesive. The pressure-sensitive adhesive is not particularly limited as long as it has a sufficient adhesive strength such that the semiconductor chip does not scatter in a dicing step, and has a low adhesive strength such that the semiconductor chip is not damaged in the subsequent semiconductor chip pickup step, and those conventionally known in the field of dicing films can be used. The pressure-sensitive adhesive may be either radiation curable or non-radiation curable. The radiation may be, for example, an ultraviolet ray. The non-radiation curable pressure-sensitive adhesive is a pressure-sensitive adhesive that exhibits constant stickiness with short term pressure. On the other hand, the radiation curable pressure-sensitive adhesive is a pressure-sensitive adhesive having a property that the stickiness is lowered by irradiation with a radiation (for example, ultraviolet ray).

The thickness of the dicing film 4 (the base material layer 2 and the pressure-sensitive adhesive layer 3) may be 60 to 150 μm or 70 to 130 μm from the viewpoint of economic efficiency and film handleability.

The dicing/die-bonding integrated film 10 can be obtained, for example, by preparing the film-shaped adhesive 1 and the dicing film 4 and sticking the film-shaped adhesive 1 and the pressure-sensitive adhesive layer 3 of the dicing film 4 together. The dicing/die-bonding integrated film 10 can also be obtained, for example, by preparing the dicing film 4 and applying the adhesive composition (adhesive varnish) onto the pressure-sensitive adhesive layer 3 of the dicing film 4 in the same manner as the method for forming the film-shaped adhesive 1.

When the film-shaped adhesive 1 and the pressure-sensitive adhesive layer 3 of the dicing film 4 are stuck together, the dicing/die-bonding integrated film 10 can be formed by laminating the film-shaped adhesive 1 on the dicing film 4 under predetermined conditions (for example, at room temperature (25° C.) or in a heated state) using a roll laminator, a vacuum laminator, or the like. The dicing/die-bonding integrated film 10 may be formed using a roll laminator in a heated state because continuous production can be carried out and efficiency is excellent.

The film-shaped adhesive and the dicing/die-bonding integrated film may be used in a process for producing a semiconductor device, or may be used in a process for producing a semiconductor device formed by stacking a plurality of semiconductor chips. The film-shaped adhesive and the dicing/die-bonding integrated film may be used in a process for producing a semiconductor device including obtaining a semiconductor chip with an adhesive piece by sticking the film-shaped adhesive or the adhesive layer of the dicing/die-bonding integrated film to a semiconductor wafer or an already singulated semiconductor chip, followed by cutting with a rotary blade or a laser, or by stretching, and bonding the semiconductor chip with an adhesive piece onto a support member or another semiconductor chip via the adhesive piece.

The film-shaped adhesive is also suitably used as an adhesive for bonding semiconductor chips in a stacked MCP (for example, a three-dimensional NAND memory) which is a semiconductor device formed by stacking a plurality of semiconductor chips.

The film-shaped adhesive can also be used as, for example, a protective sheet for protecting the back surface of a semiconductor chip of a flip-chip semiconductor device, a sealing sheet for sealing the space between the front surface of a semiconductor chip of a flip-chip semiconductor device and an adherend, or the like.

Hereinafter, a semiconductor device produced using the film-shaped adhesive and the dicing/die-bonding integrated film will be specifically described with reference to the drawings. In recent years, semiconductor devices having various structures have been proposed, and the application of the film-shaped adhesive and the dicing/die-bonding integrated film of the present embodiment is not limited to the semiconductor device having a structure described below.

### [Semiconductor Device]

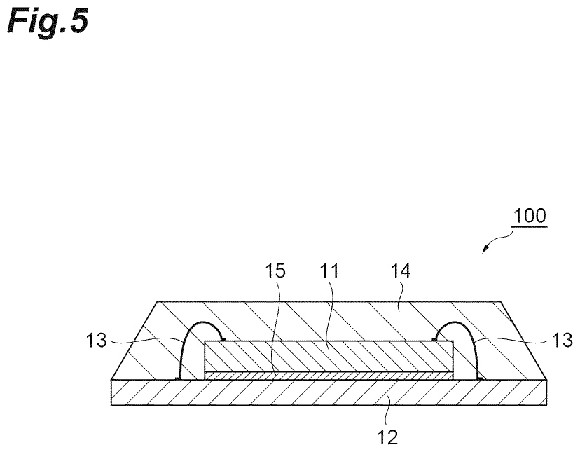

FIG. 5 is a schematic cross-sectional view showing one embodiment of a semiconductor device. A semiconductor device 100 shown in FIG. 5 includes a semiconductor chip 11 (first semiconductor chip), a support member 12 mounted with the semiconductor chip 11, and a bonding member 15. The bonding member 15 is provided between the semiconductor chip 11 and the support member 12, and bonds the semiconductor chip 11 to the support member 12. The bonding member 15 is a cured product of the adhesive composition (a cured product of the film-shaped adhesive). A connection terminal (not shown) of the semiconductor chip 11 is electrically connected to an external connection terminal (not shown) via a bonding wire 13, and sealed with a sealing material 14.

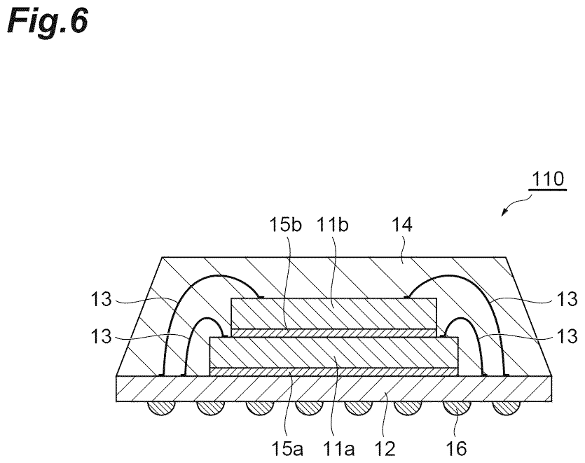

FIG. 6 is a schematic cross-sectional view showing another embodiment of a semiconductor device. In a semiconductor device 110 shown in FIG. 6, a first-stage semiconductor chip 11a (a first semiconductor chip) is bonded to a support member 12 on which a terminal 16 is formed by a bonding member 15a (a cured product of an adhesive composition (a cured product of a film-shaped adhesive)), and a second-stage semiconductor chip 11b (a second semiconductor chip) is further bonded onto the first-stage semiconductor chip 11a by a bonding member 15b (a cured product of an adhesive composition (a cured product of a film-shaped adhesive)). Connection terminals (not shown) of the first-stage semiconductor chip 11a and the second-stage semiconductor chip 11b are electrically connected to an external connection terminal via a bonding wire 13, and sealed with a sealing material 14. It can also be said that the semiconductor device 110 shown in FIG. 6 further includes another semiconductor chip (11b) stacked on the surface of the semiconductor chip (11a) in the semiconductor device 100 shown in FIG. 5.

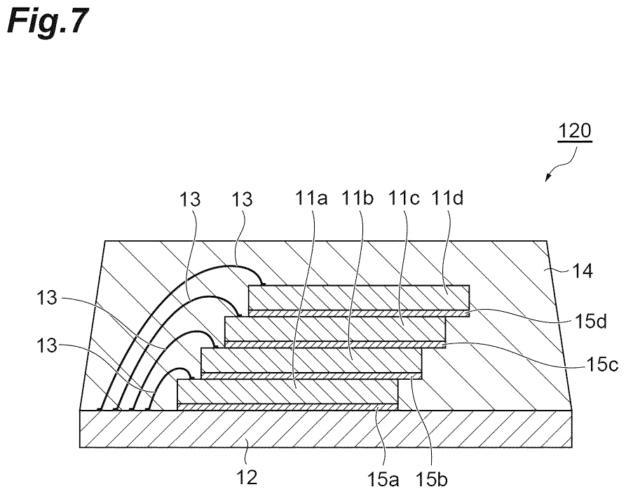

FIG. 7 is a schematic cross-sectional view showing another embodiment of a semiconductor device. A semiconductor device 120 shown in FIG. 7 includes a support member 12 and semiconductor chips 11a (first semiconductor chip), 11b (second semiconductor chip), 11c (third semiconductor chip), and 11d (fourth semiconductor chip) stacked on the support member 12. The four semiconductor chips 11a, 11b, 11c, and 11d are stacked at positions shifted from each other in the lateral direction (direction orthogonal to the stacking direction) for connection to connection terminals (not shown) formed on the surface of the support member 12 (see FIG. 7). The semiconductor chip 11a is bonded to the support member 12 by a bonding member 15a (a cured product of an adhesive composition (a cured product of a film-shaped adhesive)), and bonding members 15b, 15c, and 15d (cured products of adhesive compositions (cured products of film-shaped adhesives)) are interposed between the three semiconductor chips 11b, 11c, and 11d, respectively. It can also be said that the semiconductor device 120 shown in FIG. 7 further includes other semiconductor chips (11b, 11c, and 11d) stacked on the surface of the semiconductor chip (11a) in the semiconductor device 100 shown in FIG. 5.

Although the semiconductor device (semiconductor package) has been described in detail in the embodiments of the present disclosure, the present disclosure is not limited to the above embodiments. For example, FIG. 7 illustrates a semiconductor device of an aspect in which four semiconductor chips are stacked, but the number of semiconductor chips to be stacked is not limited thereto. In addition, in FIG. 7, a semiconductor device of an aspect in which the semiconductor chips are stacked at positions shifted from each other in the lateral direction (direction orthogonal to the stacking direction) is illustrated, but may be a semiconductor device of an aspect in which semiconductor chips are stacked at positions not shifted from each other in the lateral direction (direction orthogonal to the stacking direction).

### [Method for Producing Semiconductor Device]

The semiconductor devices (semiconductor packages) shown in FIGS. 5, 6, and 7 can be obtained by a method including interposing the film-shaped adhesive between a semiconductor chip (first semiconductor chip) and a support member or between a semiconductor chip (first semiconductor chip) and a semiconductor chip (second semiconductor chip), and bonding the semiconductor chip (first semiconductor chip) and the support member, or bonding the semiconductor chip (first semiconductor chip) and the semiconductor chip (second semiconductor chip). More specifically, the semiconductor devices can be obtained by interposing the film-shaped adhesive between a semiconductor chip and a support member or between a semiconductor chip (first semiconductor chip) and a semiconductor chip (second semiconductor chip), bonding these by thermocompression bonding, and then undergoing a thermal curing step, a wire bonding step, a sealing step with a sealing material, a heating and melting step including reflow with solder, and the like as necessary.

A method for interposing the film-shaped adhesive between a semiconductor chip (first semiconductor chip) and a support member or between a semiconductor chip (first semiconductor chip) and a semiconductor chip (second semiconductor chip) may be a method in which a semiconductor chip with an adhesive piece is prepared in advance and then stuck to a support member or another semiconductor chip as described later.

Next, an embodiment of a method for producing a semiconductor device using the dicing/die-bonding integrated film shown in FIG. 4 will be described. The method for producing a semiconductor device using the dicing/die-bonding integrated film is not limited to the method for producing a semiconductor device described below.

The semiconductor device can be obtained, for example, by a method including sticking a semiconductor wafer to the adhesive layer of the dicing/die-bonding integrated film (lamination step), preparing a plurality of singulated semiconductor chips with an adhesive piece by cutting the semiconductor wafer with the adhesive layer stuck thereto (dicing step), and bonding, as the semiconductor chip with an adhesive piece, a first semiconductor chip with an adhesive piece having a first semiconductor chip and a first adhesive piece to a support member via the first adhesive piece (bonding the semiconductor chip with an adhesive piece to the support member via the adhesive piece) (first bonding step). The method for producing a semiconductor device may further include bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece (bonding another semiconductor chip with an adhesive piece to a surface of the semiconductor chip bonded to the support member via the adhesive piece included in the another semiconductor chip with an adhesive piece) (second bonding step).

The lamination step is pressure-bonding a semiconductor wafer to the adhesive layer 1A in the dicing/die-bonding integrated film 10 to bond and hold the semiconductor wafer to stick the semiconductor wafer thereto. This step may be performed while pressing by a pressing means such as a pressure-bonding roller.

Examples of the semiconductor wafer include single crystal silicon, polycrystalline silicon, various ceramics, and compound semiconductors such as gallium arsenide.

The dicing step is dicing a semiconductor wafer. As a result, the semiconductor wafer can be cut into a predetermined size, and a plurality of singulated semiconductor chips with an adhesive piece can be produced. The dicing can be performed, for example, from the circuit surface side of the semiconductor wafer according to a conventional method. In addition, in this step, for example, a method called full cut in which a cut is provided up to the dicing film, a method in which a half cut is provided in the semiconductor wafer, and the semiconductor wafer is divided by being cooled and pulled, a method in which cutting is performed with a laser, or the like can be adopted. A dicing device used in this step is not particularly limited, and a conventionally known one can be used.

The semiconductor chip includes, for example, a circuit layer and a semiconductor layer (for example, single crystal silicon, polycrystalline silicon, various ceramics, or a compound semiconductor such as gallium arsenide). Examples of the semiconductor chip include an integrated circuit (IC). Examples of the support member include a lead frame such as a 42-alloy lead frame or a copper lead frame; a plastic film of a polyimide resin, an epoxy resin, or the like; a modified plastic film obtained by impregnating a base material such as a glass nonwoven fabric with a plastic such as a polyimide resin or an epoxy resin and curing the plastic; and a ceramic such as alumina.

The method for producing a semiconductor device may include a pickup step as necessary. The pickup step is picking up the semiconductor chip with an adhesive piece in order to peel the semiconductor chip with an adhesive piece adhesively fixed to the dicing/die-bonding integrated film. A pickup method is not particularly limited, and various conventionally known methods can be adopted. Examples of such a method include a method in which individual semiconductor chips with an adhesive piece are pushed up with a needle from the dicing/die-bonding integrated film side, and the pushed-up semiconductor chips with an adhesive piece are picked up with a pickup device.

Here, when the pressure-sensitive adhesive layer is radiation (for example, ultraviolet ray) curable, the pickup can be performed after the pressure-sensitive adhesive layer is irradiated with a radiation. As a result, the adhesive strength of the pressure-sensitive adhesive layer to the adhesive piece decreases, and the semiconductor chip with an adhesive piece is easily peeled. As a result, it is possible to perform pickup without damaging the semiconductor chip with an adhesive piece.

The first bonding step is bonding the first semiconductor chip with an adhesive piece formed by dicing to a support member for mounting the semiconductor chip via the first adhesive piece. The method for producing a semiconductor device may include bonding the second semiconductor chip with an adhesive piece to the surface of the semiconductor chip bonded to the support member via the second adhesive piece (second bonding step) as necessary. Any bonding can be performed by pressure-bonding. The pressure-bonding conditions are not particularly limited, and can be appropriately set as necessary. The pressure-bonding conditions may be, for example, a temperature of 80 to 160° C., a load of 5 to 15 N, and a time of 1 to 10 seconds. As the support member, support members similar to those described above can be exemplified.

The method for producing a semiconductor device may include further thermally curing an adhesive piece (the first adhesive piece in the first semiconductor chip with an adhesive piece and the second adhesive piece in the second semiconductor chip with an adhesive piece) or a film-shaped adhesive (thermal curing step) as necessary. Stronger adhesive fixing can be achieved by further thermally curing the adhesive pieces that bond the semiconductor chip (first semiconductor chip) and the support member, and the semiconductor chip (first semiconductor chip) and the semiconductor chip (second semiconductor chip) (the first adhesive piece in the first semiconductor chip with an adhesive piece and the second adhesive piece in the second semiconductor chip with an adhesive piece). When thermal curing is performed, curing may be performed by simultaneously applying pressure. The heating temperature in this step can be appropriately changed according to the constituent components of the adhesive piece. The heating temperature may be, for example, 60 to 200° C. or 100 to 180° C. The temperature or the pressure may be changed stepwise. The heating time may be, for example, 1 to 120 minutes or 15 to 60 minutes.

The method for producing a semiconductor device may include electrically connecting the first semiconductor chip and the second semiconductor chip to the support member with a bonding wire, more specifically, electrically connecting an electrode pad on the semiconductor chip to a tip of a terminal portion (inner lead) of the support member with a bonding wire (wire bonding step) as necessary. As the bonding wire, for example, a gold wire, an aluminum wire, a copper wire, or the like is used. The temperature when the wire bonding is performed may be in a range of 80 to 250° C. or 80 to 220° C. The heating time may be several seconds to several minutes. The wire bonding may be performed using both vibration energy by ultrasonic waves and pressure-bonding energy by applied pressure in a state of being heated within the above temperature range.

The method for producing a semiconductor device may include sealing the semiconductor chip with a sealing material (sealing step) as necessary. This step is performed to protect the semiconductor chip mounted on the support member or the bonding wire. This step can be performed by molding a resin for sealing (sealing resin) with a mold. The sealing resin may be, for example, an epoxy-based resin. The support member and the residue are embedded by heat and pressure at the time of sealing, and peeling due to bubbles at the bonding interface can be prevented.

The method for producing a semiconductor device may include completely curing the sealing resin that is insufficiently cured in the sealing step (post-curing step) as necessary. Even when the adhesive piece is not thermally cured in the sealing step, in this step, the adhesive piece is thermally cured together with the curing of the sealing resin, so that adhesive fixing can be achieved. The heating temperature in this step can be appropriately set according to the type of the sealing resin, and may be, for example, in a range of 165 to 185° C., and the heating time may be about 0.5 to 8 hours.

The method for producing a semiconductor device may include heating the semiconductor chip bonded to the support member or the semiconductor chip using a reflow furnace (heating and melting step) as necessary. In this step, the semiconductor device sealed with a resin may be surface-mounted on the support member. Examples of a surface mounting method include reflow soldering in which solder is supplied in advance onto a printed wiring board, then heated and melted by hot air or the like to perform soldering. Examples of the heating method include hot air reflow and infrared reflow. In addition, the heating method may be one that heats the entire area or one that heats a local area. The heating temperature may be, for example, in a range of 240 to 280° C.

### EXAMPLES

Hereinafter, the present disclosure will be specifically described based on examples, but the present disclosure is not limited thereto.

### [Preparation of Film-Shaped Adhesive]

### Examples 1 to 4 and Comparative Examples 1 and 2

### <Preparation of Adhesive Varnish>

Cyclohexanone was added to a mixture containing the component (A) (the component (A1) and the component (A2)) and the component (C) according to the components and the contents (unit: parts by mass) shown in Table 1, followed by stirring and mixing. To this, according to the components and the contents (unit: parts by mass) shown in Table 1, the component (B) was added, followed by stirring, and further the component (D) and the component (E) were added, followed by stirring until the respective components were homogeneous to prepare adhesive varnishes of Examples 1 to 4 and Comparative Examples 1 and 2. The components shown in Table 1 denote the following materials, and the numerical values shown in Table 1 denote parts by mass of the components (solid contents) excluding the solvent and the like.

### Component (A): Thermosetting Resin Component

### Component (A1): Epoxy Resin

(A1a-1) EXA830-CRP (trade name, manufactured by DIC Corporation, bisphenol F type epoxy resin, epoxy equivalent: 155 to 163 g/eq, softening point: 40° C. or lower, liquid at 30° C.)
(A1b-1) N-500P-10 (trade name, manufactured by DIC Corporation, o-cresol novolac type epoxy resin, epoxy equivalent: 204 g/eq, softening point: 75 to 85° C., solid at 30° C.)
(A1b-2) HP-4710 (trade name, manufactured by DIC Corporation, naphthalene type epoxy resin, epoxy equivalent: 170 g/eq, softening point: 95° C., solid at 30° C.)

### Component (A2): Phenol Resin

(A2-1) PSM-4326 (trade name, manufactured by Gun Ei Chemical Industry Co., Ltd., novolac type phenol resin, hydroxyl equivalent: 105 g/eq, softening point: 120° C.)
(A2-2) MEH-7800M (trade name, manufactured by Meiwa Plastic Industries, Ltd., phenol novolac type phenol resin, hydroxyl equivalent: 175 g/eq, softening point: 61 to 90° C.)

### Component (B): Elastomer

(B-1) SG-P3 (trade name, manufactured by Nagase ChemteX Corporation, acrylic rubber, weight average molecular weight: 800,000, Tg: 12° C.)

### Component (C): Inorganic Filler

(C-1) Silica filler dispersion (manufactured by CIK NanoTek Corporation, silica filler, average particle diameter: 0.10 μm)
(C-2) SC2050-HLG (trade name, manufactured by Admatechs Co., Ltd., silica filler dispersion, average particle diameter: 0.50 μm)
(C-3) R972 (trade name, manufactured by NIPPON AEROSIL CO., LTD., silica, average particle diameter 0.016 μm)

### Component (D): Coupling Agent

(D-1) Z-6119 (trade name, manufactured by Dow Toray Co., Ltd., γ-ureidopropyltriethoxysilane)
(D-2) A-189 (trade name, manufactured by Nippon Unicar Company Limited, γ-mercaptopropyltrimethoxysilane)

### Component (E): Curing Accelerator

(E-1) 2PZ-T (trade name, manufactured by SHIKOKU CHEMICALS CORPORATION, 2-phenylimidazole)
(E-2) 2PZ-CN (trade name, manufactured by SHIKOKU CHEMICALS CORPORATION, 1-cyanoethyl-2-phenylimidazole)

### <Preparation of Film-Shaped Adhesive>

Each of the adhesive varnishes of Examples 1 to 4 and Comparative Examples 1 and 2 was filtered through a 100 mesh filter and then subjected to vacuum defoaming. A 38 μm-thick polyethylene terephthalate (PET) film subjected to a release treatment was prepared as a support film, and the adhesive varnish after vacuum defoaming was applied onto the PET film. The applied adhesive varnish was heated and dried at 90° C. for 5 minutes and then at 140° C. for 5 minutes to obtain film-shaped adhesives of Examples 1 to 4 and Comparative Examples 1 and 2 in the B-stage state. In the film-shaped adhesives of Examples 1 to 4 and Comparative Examples 1 and 2, the thickness of the film-shaped adhesive was adjusted to 5 μm by the application amount of the adhesive varnish.

### [Evaluation of Film-Shaped Adhesive]

### <Evaluation of Thin Film Formability>

The coated surfaces of the film-shaped adhesives of Examples 1 to 4 and Comparative Examples 1 and 2 were visually checked, and evaluated as to whether a defect such as a spot, a missing spot, or a streak exists. One in which no defect was observed was evaluated as “A”, and one in which a defect was observed was evaluated as “B”. The results are shown in Table 1.

### <Measurement of Onset Temperature, Peak Temperature, and Calorific Value>

Each of the film-shaped adhesives (10±0.5 mg) of Examples 1 to 4 and Comparative Examples 1 and 2 was weighed in an aluminum pan (manufactured by Epolead Service Inc.), an aluminum lid was placed thereon, and an evaluation sample was sealed in a sample pan using a crimper. DSC was measured at a temperature raising rate of 10° C./min in a measurement temperature range of 30 to 300° C. in a nitrogen atmosphere using a differential scanning calorimeter (Thermo plus DSC8235E, manufactured by Rigaku Corporation). As a means for analyzing the calorific value, a total area analysis method was used. The calorific value (unit: J/g) was calculated by giving an instruction for an analysis in the temperature range of 30° C. to 300° C. in each DSC curve to specify a baseline of the analysis temperature range and integrate the peak area. As a means for analyzing the onset temperature, an analysis method for total area was used, and an intersection point of a baseline and a maximum inclination point of an exothermic peak in each DSC curve was calculated by giving an instruction for an analysis in a temperature range of 30° C. to 300° C., and the onset temperature (unit: ° C.) was obtained. As a means for analyzing the onset temperature, the maximum point of the exothermic peak was obtained, and the peak temperature (unit: ° C.) was obtained. The results are shown in Table 1.

### <Measurement of Storage Modulus>

The storage modulus after curing was measured using the film-shaped adhesives of Examples 1 to 4 and Comparative Examples 1 and 2. The storage modulus after curing was measured by the following method. That is, a plurality of film-shaped adhesives having a thickness of 5 μm were stacked to a thickness of 20 μm or more, and this was sized to a width of 4 mm×a length of 20 mm or more to prepare a sample for measurement. The prepared sample was cured under the conditions of 140° C. and 30 minutes, then the sample after curing (cured product) was set in a dynamic viscoelasticity measuring device (Rheogel E-4000, manufactured by UBM Co., Ltd.), and dynamic viscoelasticity was measured in a temperature-dependent measurement mode in which measurement is performed from room temperature (25° C.) to 300° C. under the conditions of a chuck distance of 20 mm, a frequency of 10 Hz, and a temperature raising rate of 3° C./minute under a tensile load, the value of the storage modulus at 150° C. was read, and the value was taken as the storage modulus at 150° C. The results are shown in Table 1. The storage modulus at 150° C. indicates that the larger the numerical value (for example, 50 MPa or more) is, the more the brittleness of the semiconductor chip due to film thinning can be compensated, and as a result, occurrence of chip cracks can be prevented. The results are shown in Table 1.

TABLE 1

| | | | | | | | Comp. | Comp. |
|---|---|---|---|---|---|---|---|---|
| | | | Exam. 1 | Exam. 2 | Exam. 3 | Exam. 4 | Exam. 1 | Exam. 2 |
| (A) | (A1) | (Ala-1) | 12.3 | 13.0 | 15.6 | 10.5 | — | 13.1 |
| | | (Alb-1) | 27.9 | — | — | — | 10.6 | 10.4 |
| | | (Alb-2) | 1.5 | 19.3 | 23.2 | 15.7 | — | — |
| | (A2) | (A2-1) | 26.2 | 17.1 | 20.6 | — | — | — |
| | | (A2-2) | — | — | — | 23.3 | 9.6 | 19.1 |
| (B) | (B-1) | | 31.5 | 30.0 | 30.0 | 30.0 | 69.8 | 18.0 |
| (C) | (C-1) | | — | 20.0 | 10.0 | 20.0 | — | — |
| | (C-2) | | — | — | — | — | — | 39.0 |
| | (C-3) | | — | — | — | — | 8.3 | — |
| (D) | (D-1) | | 0.13 | 0.13 | 0.13 | 0.13 | 0.40 | 0.09 |
| | (D-2) | | 0.20 | 0.26 | 0.26 | 0.26 | 1.26 | 0.18 |
| (E) | (E-1) | | 0.27 | 0.18 | 0.22 | 0.15 | — | — |
| | (E-2) | | — | — | — | — | 0.02 | 0.06 |
| Thin film formability | | | A | A | A | A | A | B |
| DSC | Onset | | 152.6 | 145.8 | 146.0 | 128.1 | 192.9 | 147.4 |
| | temperature (° C.) | | | | | | | |
| | Peak temperature | | 171.9 | 163.8 | 163.8 | 169.4 | 215.2 | 193.7 |
| | (° C.) | | | | | | | |
| | Calorific value | | 175 | 130 | 159 | 118 | 32 | 77 |
| | (J/g) | | | | | | | |
| Storage | 150° C., MPa | | 189 | 140 | 120 | 104 | 2 | 12 |
| modulus | | | | | | | | |

As shown in Table 1, in the storage modulus at 150° C. of the cured product obtained when the film-shaped adhesive was cured under the conditions of 140° C. and 30 minutes, the film-shaped adhesives of Examples 1 to 4 which satisfy the predetermined requirements showed a sufficiently high numerical value as compared with the film-shaped adhesives of Comparative Examples 1 and 2 which do not satisfy the predetermined requirements. From these results, it was verified that the occurrence of chip cracks can be sufficiently prevented even when the film-shaped adhesive of the present disclosure is cured under heating conditions of a low temperature and a short time.

### REFERENCE SIGNS LIST

1: film-shaped adhesive, 1A: adhesive layer, 2: base material layer, 3: pressure-sensitive adhesive layer, 4: dicing film, 10: dicing/die-bonding integrated film, 11, 11a, 11b, 11c, 11d: semiconductor chip, 12: support member, 13: bonding wire, 14: sealing material, 15, 15a, 15b, 15c, 15d: bonding member, 16: terminal, 100, 110, 120: semiconductor device

1. A film-shaped adhesive, comprising: a thermosetting resin component; and an elastomer, wherein
in a DSC curve of the film-shaped adhesive obtained by performing differential scanning calorimetry under conditions of a temperature raising rate of 10° C./min and a measurement temperature range of 30 to 300° C., an onset temperature of an exothermic peak observed in the DSC curve is 165° C. or lower, a peak temperature is 185° C. or lower, and a calorific value is 90 J/g or more.

2. The film-shaped adhesive according to claim 1, optionally further comprising an inorganic filler, wherein
a content of the inorganic filler is 0 to 25% by mass with respect to a total amount of the film-shaped adhesive.

3. The film-shaped adhesive according to claim 1, wherein
the thermosetting resin component comprises an epoxy resin.

4. The film-shaped adhesive according to claim 3, wherein
the thermosetting resin component further comprises a phenol resin.

5. The film-shaped adhesive according to claim 1, wherein
a thickness of the film-shaped adhesive is 1 to 15 μm.

6. The film-shaped adhesive according to claim 1, wherein
a storage modulus at 150° C. of a cured product obtained when the film-shaped adhesive is cured under conditions of 140° C. and 30 minutes is 80 MPa or more.

7. The film-shaped adhesive according to claim 1, wherein
the film-shaped adhesive is used in a process for producing a semiconductor device formed by stacking a plurality of semiconductor chips.

8. The film-shaped adhesive according to claim 7, wherein
the semiconductor device is a three-dimensional NAND memory.

9. A dicing/die-bonding integrated film, comprising:
a base material layer; a pressure-sensitive adhesive layer; and an adhesive layer made of the film-shaped adhesive according to claim 1, wherein
the pressure-sensitive adhesive layer is located between the base material layer and the adhesive layer made of the film-shaped adhesive.

10. A semiconductor device, comprising:
a first semiconductor chip;
a support member mounted with the first semiconductor chip; and
a cured product of the film-shaped adhesive according to claim 1, the cured product being provided between the first semiconductor chip and the support member and bonding the first semiconductor chip to the support member.

11. The semiconductor device according to claim 10, further comprising
a second semiconductor chip different from the first semiconductor chip, the second semiconductor chip being stacked on a surface of the first semiconductor chip.

12. A method for producing a semiconductor device, the method comprising:
sticking the adhesive layer of the dicing/die-bonding integrated film according to claim 9 to a semiconductor wafer;
preparing a plurality of singulated semiconductor chips with an adhesive piece by cutting the semiconductor wafer with the adhesive layer stuck thereto; and
bonding, as the semiconductor chip with an adhesive piece, a first semiconductor chip with an adhesive piece having a first semiconductor chip and a first adhesive piece to a support member via the first adhesive piece.

13. The method for producing a semiconductor device according to claim 12, further comprising:
thermally curing the first adhesive piece in the first semiconductor chip with an adhesive piece under conditions of 100 to 180° C. and 15 to 60 minutes; and
electrically connecting the first semiconductor chip to the support member with a bonding wire.

14. The method for producing a semiconductor device according to claim 12, further comprising:
bonding, as the semiconductor chip with an adhesive piece, a second semiconductor chip with an adhesive piece having a second semiconductor chip and a second adhesive piece to a surface of the first semiconductor chip in the first semiconductor chip with an adhesive piece bonded to the support member via the second adhesive piece.

15. The method for producing a semiconductor device according to claim 14, further comprising:
thermally curing the first adhesive piece in the first semiconductor chip with an adhesive piece and the second adhesive piece in the second semiconductor chip with an adhesive piece under conditions of 100 to 180° C. and 15 to 60 minutes; and
electrically connecting the first semiconductor chip and the second semiconductor chip to the support member with a bonding wire.

16. A method for producing a semiconductor device, the method comprising:
interposing the film-shaped adhesive according to claim 1 between a first semiconductor chip and a support member, or between a first semiconductor chip and a second semiconductor chip different from the first semiconductor chip, and bonding the first semiconductor chip and the support member, or the first semiconductor chip and the second semiconductor chip.

17. The method for producing a semiconductor device according to claim 16, further comprising:
thermally curing the film-shaped adhesive under conditions of 100 to 180° C. and 15 to 60 minutes; and
electrically connecting the first semiconductor chip and the second semiconductor chip to the support member with a bonding wire.

18. The film-shaped adhesive according to claim 1, wherein the film-shaped adhesive further comprises an inorganic filler having a content that is less than or equal to 25% by mass with respect to the total amount of the film-shaped adhesive.

19. The film-shaped adhesive according to claim 1, wherein the film-shaped adhesive comprises a negligible amount, or none, of an inorganic filler.
